(19) United States
(12) Patent Application Publication
(10) Pub. No.: US 2011/0031518 A1
(43) Pub. Date: Feb. 10, 2011

(54) LED DEVICE

(76) Inventors: Chin-Yuan CHENG, Shulin City (TW); Hong-Long CHEN, Shulin City (TW)

Correspondence Address: Muncy, Geissler, Olds & Lowe, PLLC, 4000 Legato Road, Suite 310, FAIRFAX, VA, 22033, US

(21) Appl. No.: 12/840,563

(22) Filed: Jul. 21, 2010

(30) Foreign Application Priority Data
Aug. 5, 2009 (TW) 098214485

(51) Int. Cl. H01L 33/60

(52) U.S. Cl. 257/98; 257/E33.073

(57) ABSTRACT

A LED device includes a LED having a light-emitting surface and adapted for emitting light through the light-emitting surface, and a reflector formed of three or more than three reflecting layers having the peripheral surfaces thereof sloping at different angles and arranged in a stack on the light-emitting surface of the LED for letting the light emitted by the LED pass and/or reflecting and/or refracting the light to enhance luminous uniformity and luminous brightness and to avoid light concentration at the center or the formation of a corona.

This application claims the priority benefit of Taiwan patent application number 098214485 filed on Aug. 5, 2009.

### BACKGROUND OF THE INVENTION

1. Field of the Invention

The present invention relates to LED technology and more particularly, to a LED device, which enhances luminous uniformity and luminous brightness and avoids light concentration at the center or the formation of a corona.

2. Description of the Related Art

Since the invention of light bulb, many different types of lamps, such as fluorescent lamp and power-saving lamp, have been continuously developed for different applications. However, conventional lamps have the common drawbacks of high power consumption, quick light attenuation, short service life, fragile characteristic, and being not reclaimable. Nowadays, in view of the world trend of energy-saving and carbon-reduction, LED (light emitting diode) has been intensively used in embedded lamps, head lamps and many other different lighting fixtures to substitute for conventional lighting fixtures for the advantages of excellent photoelectric conversion efficiency, constant wavelength, adjustability of luminous flux and light quality, small size, low heat value and long lifespan.

FIG. 12 illustrates a LED device according to the prior art. According to this design the LED device A comprises a LED chip A1 and a packing resin A2 packed on the LED chip A1. This design of LED device has drawbacks as follows:

1. During operation of the LED device A, light concentration at the center will occur (see FIG. 13), lowering the luminous performance, shortening the luminous range and narrowing the luminous area (see FIG. 14).

2. For wide area lamination, multiple LED devices must be used, increasing the cost and power consumption.

Therefore, it is desirable to provide a LED device, which eliminates the aforesaid problems.

### SUMMARY OF THE INVENTION

The present invention has been accomplished under the circumstances in view. It is the main object of the present invention to provide a LED device, which enhances luminous uniformity and luminous brightness and avoids light concentration at the center or the formation of a corona.

To achieve this and other objects of the present invention, a LED device comprises a LED that has a light-emitting surface located on the top side thereof and a plurality of conducting pins disposed remote from the light-emitting surface for connection to a circuit module that provides the necessary power and control program, and a reflector located on the light-emitting surface of the LED. The reflector is formed of three or more than three reflecting layers that have different shapes and slope at different angles for letting light pass and/or reflecting and/or refracting light.

Further, the luminous range of the light emitted by the LED through the light-emitting surface can be from 0° to ±90°. Further, the reflector comprises a bottom reflecting layer, a top reflecting layer and at least one intermediate reflecting layer sandwiched between the top reflecting layer and the bottom reflecting layer. When the light goes through the light-emitting surface into the reflecting layers of the reflector, the top reflecting layer reflects or refracts the light that goes through the light-emitting surface within the range of 0° to ±20° toward the outside; the intermediate reflecting layer reflects or refracts the light that goes through the light-emitting surface within the range of ±21° to ±50° toward the outside or the top reflecting layer; the bottom reflecting layer reflects or refracts the light that goes through the light-emitting surface within the range of ±51° to ±90° toward the outside or the intermediate reflecting layer and top reflecting layer.

Further, the top reflecting layer of the reflector is a triangle cone of which the internal angles defined by the sides and the base are about 60° (and within the range of)60°±5°. The diameter of the base of the triangle cone of the top reflecting layer is equal to the length of the light-emitting surface of the LED. The intermediate reflecting layer of the reflector is a truncated cone. The slope angle of the sloping periphery of the intermediate reflecting layer is not equal to the slope angle of the sides of the triangle cone of the top reflecting layer. The sloping periphery of the intermediate reflecting layer define with the normal line a contained angle within the range of 13°˜25°.

### BRIEF DESCRIPTION OF THE DRAWINGS

FIG. 1 is an exploded view of a LED device in accordance with the present invention.

FIG. 2 is a schematic side view of the reflector of the LED device in accordance with the present invention (I).

FIG. 3 is a schematic side view of the reflector of the LED device in accordance with the present invention (II).

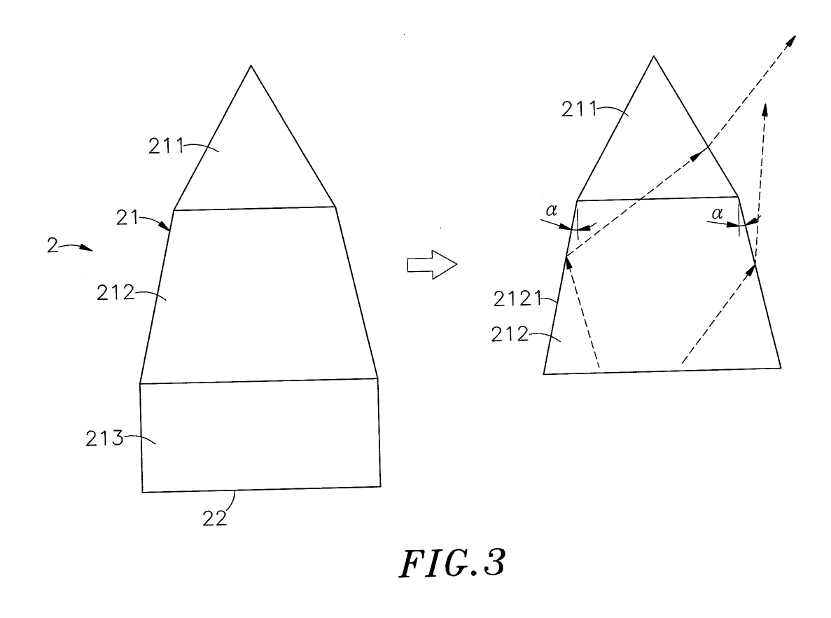

FIG. 4 is a schematic side view of the reflector of the LED device in accordance with the present invention (III).

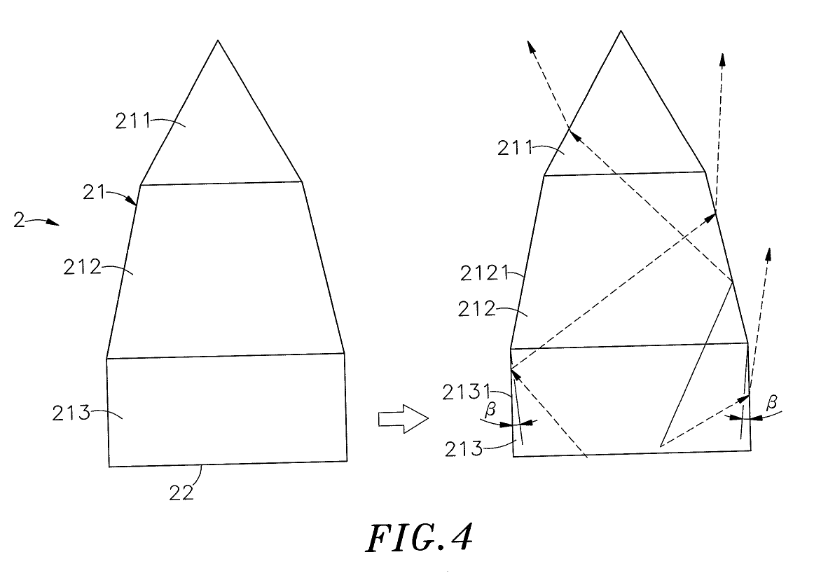

FIG. 5 is a side view of the LED device in accordance with the present invention, showing the reflector kept above the LED at a distance.

FIG. 6 is a side view of the LED device in accordance with the present invention, showing the reflector directly bonded to the light-emitting surface of the LED.

FIG. 7 is a side view of an alternate form of the reflector for the LED device in accordance with the present invention.

FIG. 8 is a side view of another alternate form of the reflector for the LED device in accordance with the present invention.

FIG. 9 is a luminous range diagram obtained from the LED device in accordance with the present invention.

FIG. 10 is a diagram of angle of projection obtained from the LED device in accordance with the present invention.

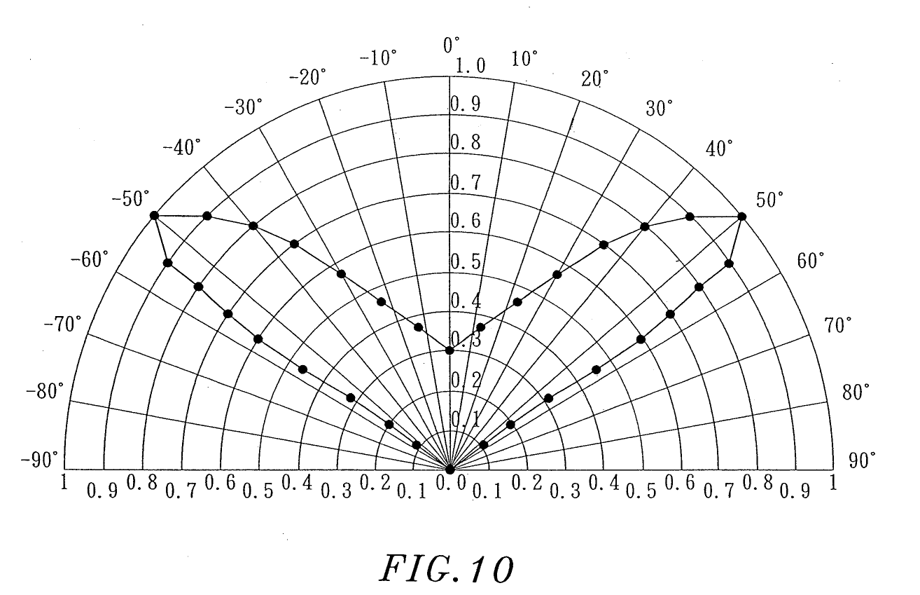

FIG. 11 is an exploded view of a LED lamp made according to the present invention.

FIG. 12 is a perspective view of a LED device according to the prior art.

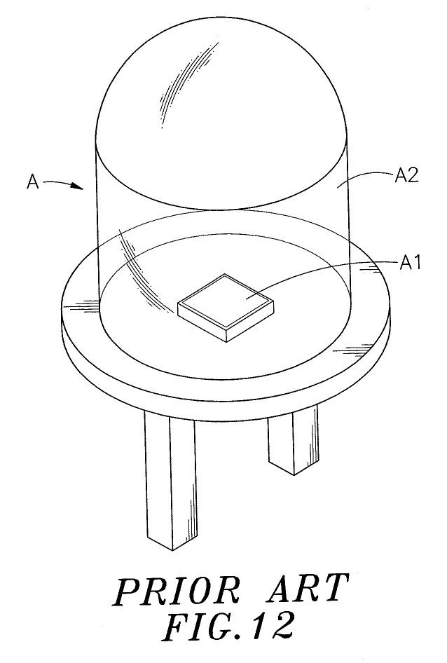

FIG. 13 a luminous range diagram obtained from the LED device according to the prior art.

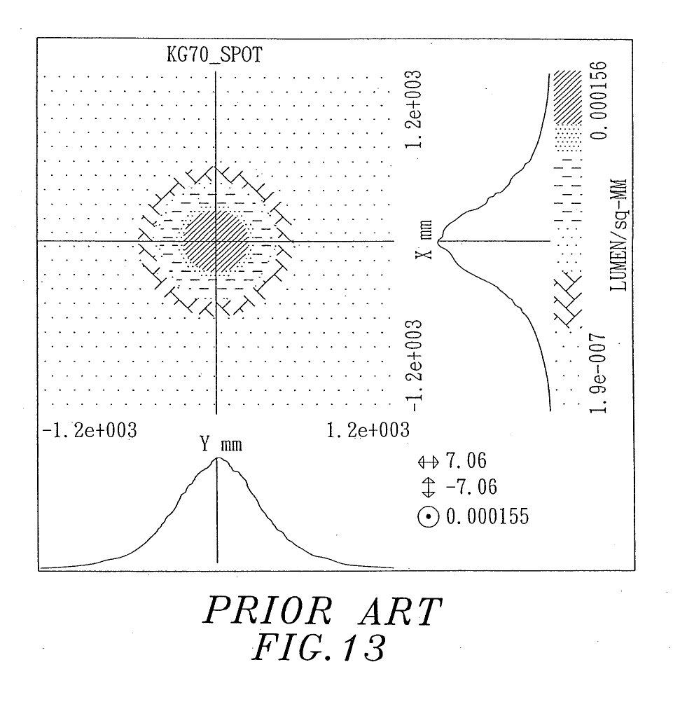

FIG. 14 is a diagram of angle of projection obtained from the LED device according to the prior art.

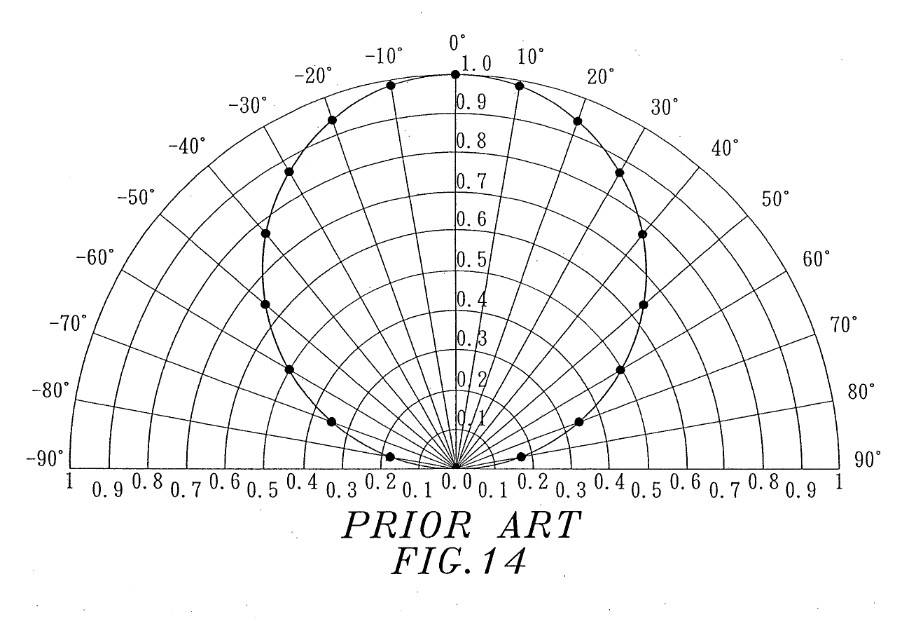

### DETAILED DESCRIPTION OF THE PREFERRED EMBODIMENT

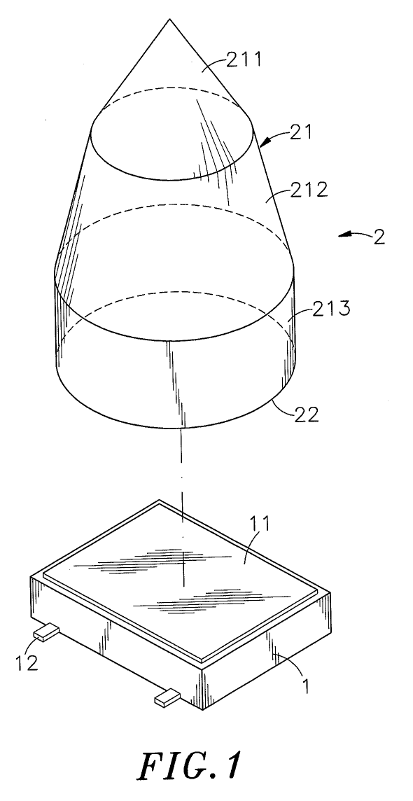

Referring to FIGS. 1˜4, a LED device in accordance with the present invention can be a high-brightness LED device, comprising a LED 1 and a reflector 2.

The LED 1 can be, for example, a LED chip, having a light-emitting surface 11 located on the top side thereof and a plurality of conducting pins 12 disposed remote from the light-emitting surface 11.

The reflector 2 comprises a plurality of reflecting layers 21 laminated on one another. The reflecting layers 21 include a top reflecting layer 211, at least one intermediate reflecting layer 212 and a bottom reflecting layer 213.

During installation, the bottom (base) 22 of the reflecting layers 21 of the reflector 2 is bonded to or kept above the light-emitting surface 11 of the LED 1. During operation of the LED device, the LED 1 emits light through the light-emitting surface 11 into the reflector 2, enabling the emitted light to be reflected by the top reflecting layer 211, at least one intermediate reflecting layer 212 and bottom reflecting layer 213 of the reflector 2 toward the outside in different directions. According to this embodiment, the number of the at least one intermediate reflecting layer 212 is one.

The LED 1 can be a SMT (surface mount technology) LED, through-hole LED or organic LED.

The top reflecting layer 211 of the reflector 2 is a triangle cone of which the internal angles θ1; θ2 defined by the sides and the base are about 60° (and within the range of 60°±5°). The diameter of the base of the triangle cone of the top reflecting layer 211 is equal to the length of the light-emitting surface 11 of the LED 1. The intermediate reflecting layer 212 of the reflector 2 is a truncated cone. The slope angle of the sloping periphery 2121 of the intermediate reflecting layer 212 is not equal to the slope angle of the sides of the triangle cone of the top reflecting layer 211. The sloping periphery 2121 of the intermediate reflecting layer 212 define with the normal line a contained angle α within the range of 13°˜25°.

The bottom reflecting layer 213 of the reflector 2 is a cylinder having its top bonded to the base of the truncated cone of the intermediate reflecting layer 212. The cylinder of the bottom reflecting layer 213 can be a right cylinder of which the surface 2131 is a curved surface. Alternatively, the cylinder of the bottom reflecting layer 213 can be a tapered cylinder of which the surface 2131 is a tapered surface gradually reducing in direction from the bottom reflecting layer 213 toward the top reflecting layer 211. The surface 2131 and bottom (base) of the cylinder of the bottom reflecting layer 213 define a contained angle β within the range of 0°˜8°. Further, the reflecting layers 21 of the reflector 2 are peripherally polished, enhancing light transmission and reflection effects.

The reflecting layers 21 of the reflector 2 are prepared from an optical thermoplastic material, such as polycarbonate (PC), polymethylmethacrylate (PMMA), silicon or cyclic olefin copolymer (COC) E480R.

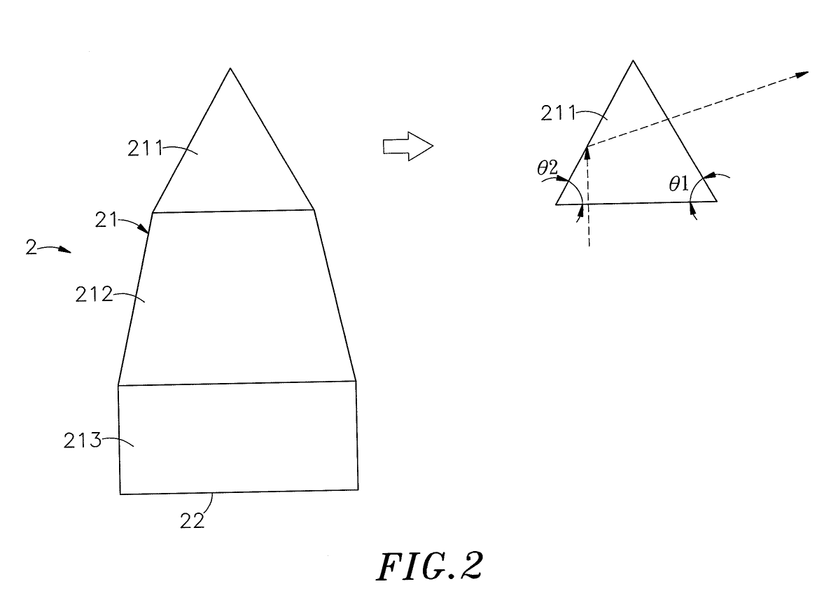

Referring to FIGS. 5 and 6 and FIGS. 2˜4 again, the luminous range of the light emitted by the LED 1 through the light-emitting surface 11 can be from 0° to ±90°. When the light goes through the light-emitting surface 11 into the reflecting layers 21 of the reflector 2, the top reflecting layer 211 reflects or refracts the light that goes through the light-emitting surface 11 within the range of 0° to ±20° toward the outside; the intermediate reflecting layer 212 reflects or refracts the light that goes through the light-emitting surface 11 within the range of ±21° to ±50° toward the outside or the top reflecting layer 211; the bottom reflecting layer 213 reflects or refracts the light that goes through the light-emitting surface 11 within the range of ±51° to ±90° toward the outside or the intermediate reflecting layer 212 and top reflecting layer 211.

When the emitted light goes through the light-emitting surface 11 into the reflecting layers 21 of the reflector 2, the light transmission path is determined subject to Snell's law in geometric optics:

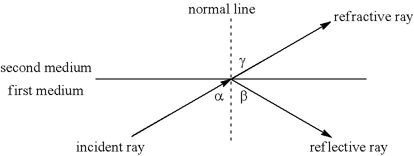

When incident ray goes out of the incident medium into the boundary (interface) between the first and second media, an angle of incidence α, an angle of reflection β and angle of refraction γ are produced. When it meets the condition of total reflection, incident ray is totally reflected by the boundary (interface) between the first and second media without entering the second medium; when it does not meet the condition of total reflection, incident ray is either refracted or reflected subject to Snell's law, depending on the refractive indices of the media and the angle of incidence.

Therefore, when the emitted light goes through the light-emitting surface 11 into the reflecting layers 21 of the reflector 2, the incident light enters the bottom reflecting layer 213 at first. At this time, the incident light within the range of ±51° to ±90° goes toward the outside, and the other part of the incident light is reflected into the intermediate reflecting layer 212; the incident light within the range of ±21° to ±50° goes toward the outside, and the other part of the incident light entering the intermediate reflecting layer is reflected by the intermediate reflecting layer 212 into the top reflecting layer 211; the incident light entering the top reflecting layer 211 within the range of 0° to ±20° goes toward the outside, and the other part of the incident light entering the top reflecting layer 211 is reflected or refracted by the top reflecting layer 211 toward the outside, enhancing luminous brightness.

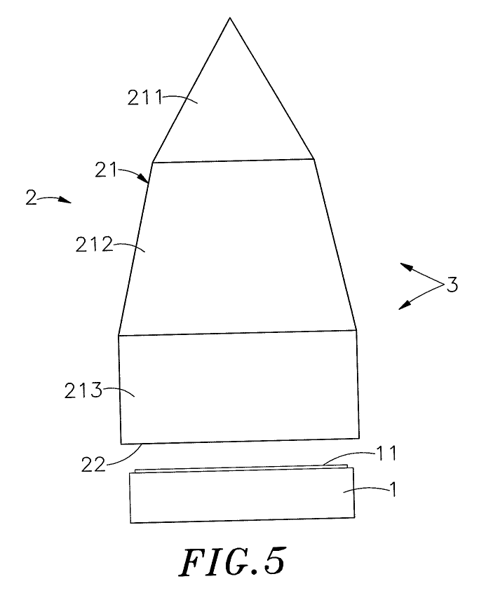

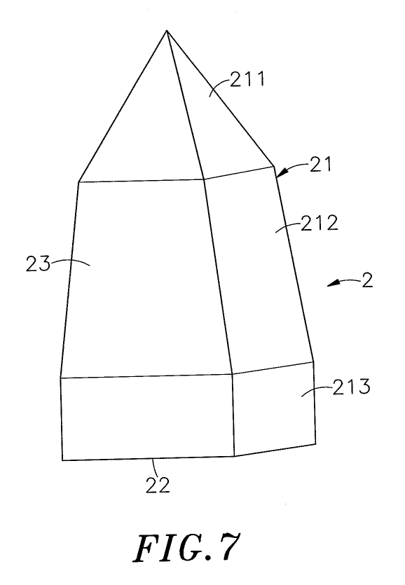

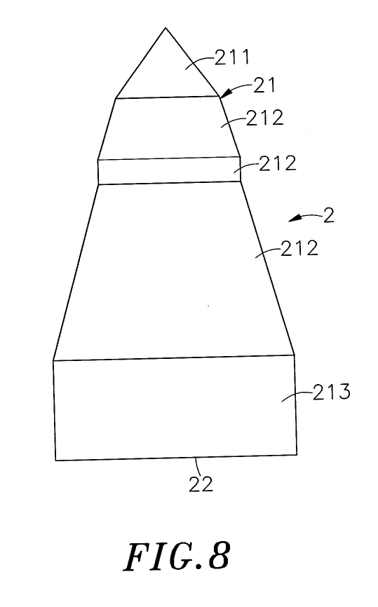

Referring to FIGS. 7 and 8 and FIGS. 5 and 6 again, the reflecting layers 21 of the reflector 2 can be made in the shape of a cylinder, triangle cone or prism, providing multiple reflecting surfaces 23 to effectively reflect light emitted by the LED 1. Further, the bottom (base) 22 of the reflecting layers 21 of the reflector 2 can be directly bonded to the light-emitting surface 11 of the LED 1, or kept apart from the light-emitting surface 11 of the LED 1 by spacer means. Further, the LED 1 and the reflector 2 can be positioned on a circuit board in a lighting fixture to achieve a wide-area, high-brightness luminous effect.

Further, each intermediate reflecting layer 212 of the reflector 2 between the top reflecting layer 211 and the bottom reflecting layer 213 is a truncated cone, and the slope angle of the sloping periphery 2121 of the intermediate reflecting layer 212 is not equal to the slope angle of the sides of the triangle cone of the top reflecting layer 211. When multiple intermediate reflecting layer 212 are connected in series between the top reflecting layer 211 and the bottom reflecting layer 213, the sloping peripheries 2121 of the intermediate reflecting layers 212 are kept in flush with the periphery of the top reflecting layer 211 and the periphery of the bottom reflecting layer 213, enhancing light reflection

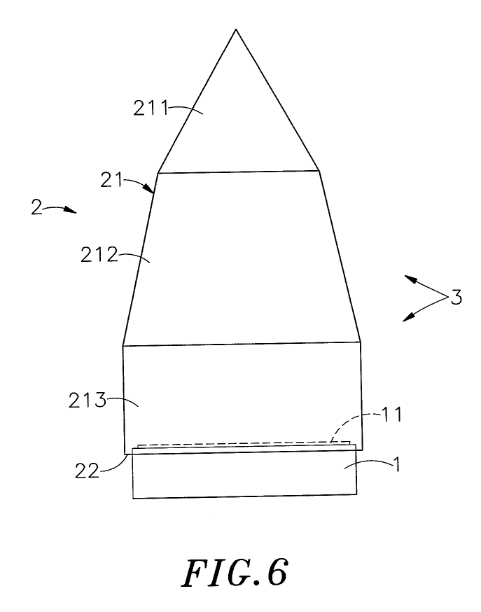

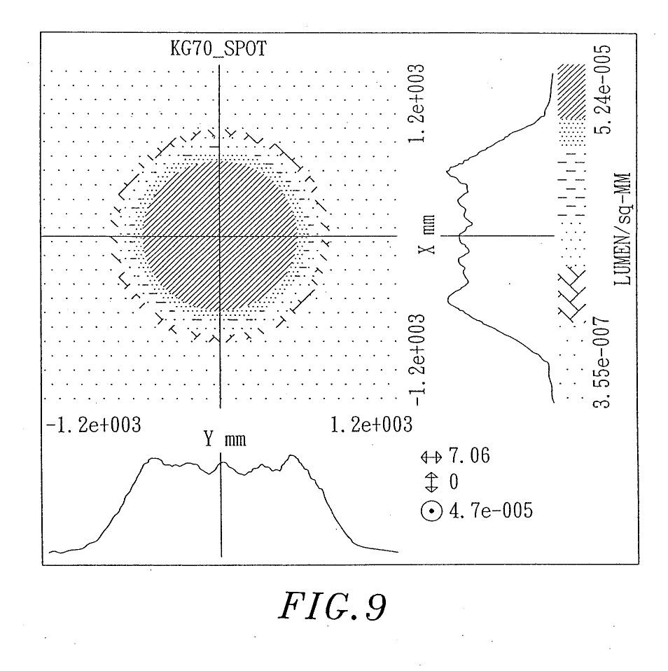

Referring to FIGS. 9˜11 and FIGS. 5 and 6 again, when the emitted light goes through the light-emitting surface 11 into the reflecting layers 21 of the reflector 2, the top reflecting layer 211, the intermediate reflecting layers 212 and the bottom reflecting layer 213 reflect and/or refract the light toward the outside in a diffused manner, widening the luminous range and enhancing the luminous brightness. Further, subject to the triangle cone design of the top reflecting layer 211, the truncated cone design of the intermediate reflecting layer 212 that slopes at about 13°˜25° and the tapered cylindrical design of the bottom reflecting layer 213 that slopes at 0°˜8°, the light rays that go through the light-emitting surface 11 into the reflecting layers 212 of the reflector 2 are directly guided outwards, or reflected or refracted toward the outside, enhancing luminous uniformity and luminous brightness and avoiding light concentration at the center or the formation of a corona. Thus, the high-brightness LED device 3 is practical for use to make a LED lamp.

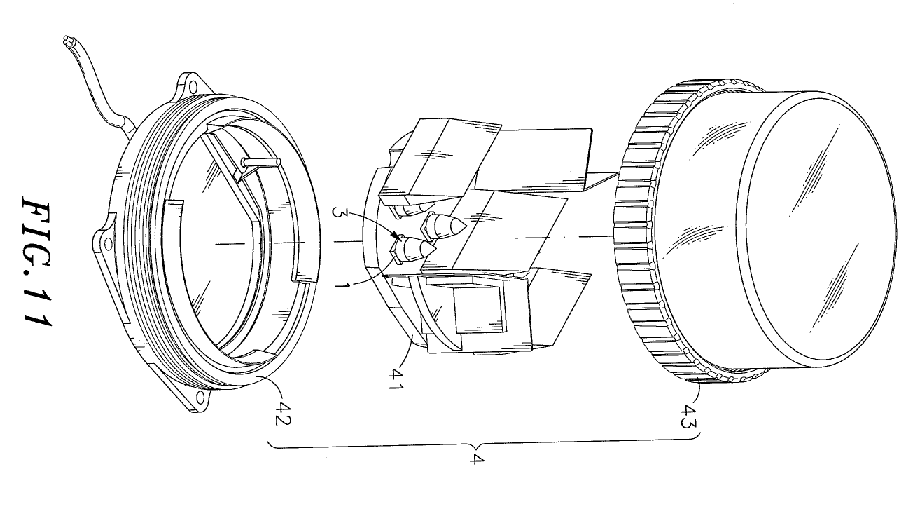

Referring to FIG. 11 again, a number of high-brightness LED devices 3 can be installed in a circuit board 41 in a holder shell 42 and covered with a transparent cover 43, thereby forming a LED lamp 4. The LED lamp 4 has the characteristics of wide range of luminous intensities and high luminous brightness.

In actual practice, the invention has the advantages and characteristics as follows:
1. The high-brightness LED device 3 comprises a LED 1, and a reflector 2 formed of multiple reflecting layers 21 of different shapes and bonded to the light-emitting surface 11 of the LED 1 to reflect and/or refract the light emitted by the LED 1, enhancing luminous brightness and uniformity and widening the range of luminous intensities.
2. A limited number of high-brightness LED devices 3 is sufficient for making a high-performance LED lamp practical for a wide area lamination with less consumption of power supply, achieving satisfactory economic benefits.

In conclusion, the invention provides a high-brightness LED device consisting of a LED and a reflector bonded to the light-emitting surface of the LED, and providing enhanced luminous brightness and uniformity and a widened range of luminous intensities.

Although particular embodiments of the invention have been described in detail for purposes of illustration, various modifications and enhancements may be made without departing from the spirit and scope of the invention.

What the invention claimed is:

1. A high-brightness LED device, comprising:
a LED having a light-emitting surface and adapted for emitting light through said light-emitting surface; and
a reflector bonded to said light-emitting surface of said LED, said reflector comprising at least three reflecting layers arranged on said light-emitting surface of said LED, each said reflecting layer having a peripheral surface sloping at a different angle for letting the light emitted by said LED pass and/or reflecting and/or refracting the light emitted by said LED.

2. The high-brightness LED device as claimed in claim 1, wherein said LED is selected from a group consisting of SMT (surface mount technology) LED, through-hole LED, LED chip and organic LED.

3. The high-brightness LED device as claimed in claim 1, wherein said reflecting layers of said reflector are prepared from an optical thermoplastic material selected from a group consisting of polycarbonate (PC), polymethylmethacrylate (PMMA), silicon and cyclic olefin copolymer (COC) E480R.

4. The high-brightness LED device as claimed in claim 1, wherein said reflector comprises a bottom reflecting layer bonded to said light-emitting surface of said LED, a top reflecting layer and at least one intermediate reflecting layer sandwiched between said top reflecting layer and said bottom reflecting layer.

5. The high-brightness LED device as claimed in claim 4, wherein the luminous range of the light emitted by said LED through said light-emitting surface is within the range from 0° to ±90°; said top reflecting layer is a triangle cone and adapted for refracting the light that goes through said light-emitting surface of said LED within the range of 0° to ±20° towards the outside.

6. The high-brightness LED device as claimed in claim 5, wherein the size of the base of the triangle cone of said top reflecting layer is equal to the size of said light-emitting surface of said LED, and the internal angles defined by the sides and base of the triangle cone of said top reflecting layer are about 60°±5°.

7. The high-brightness LED device as claimed in claim 4, wherein the luminous range of the light emitted by said LED through said light-emitting surface is within the range from 0° to ±90°; said at least one intermediate reflecting layer is a truncated cone and adapted for reflecting and refracting the light that goes through said light-emitting surface of said LED within the range of ±21° to ±50° towards the outside and into said top reflecting layer

8. The high-brightness LED device as claimed in claim 4, wherein the sloping periphery of each said intermediate reflecting layer define with the normal line a contained angle within the range of 13°˜25°.

9. The high-brightness LED device as claimed in claim 4, wherein the luminous range of the light emitted by said LED through said light-emitting surface is within the range from 0° to ±90°; said bottom reflecting layer is a cylinder and adapted for reflecting and refracting the light that goes through said light-emitting surface of said LED within the range of ±51° to ±90° towards the outside and into said at least one intermediate layer and said top reflecting layer.

10. The high-brightness LED device as claimed in claim 4, wherein the peripheral surface and bottom of the cylinder of said bottom reflecting layer define a contained angle within the range of 0°˜8°.

11. The high-brightness LED device as claimed in claim 1, wherein said reflector has a bottom wall thereof kept spaced said light-emitting surface of said LED at a predetermined distance.
